(19) United States
(12) Patent Application Publication
(10) Pub. No.: US 2007/0139069 A1
(43) Pub. Date: Jun. 21, 2007

(54) Method and apparatus for testing a liquid crystal cell

(75) Inventor: Yasuhiro Miyake, Tokyo (JP)

Correspondence Address: Paul D. Greeley;Ohlandt, Greeley, Ruggiero & Perle, L.L.P., One Landmark Square, 10th Floor, Stamford, CT, 06901-2682, US

(73) Assignee: Agilent Technologies, Inc.

(21) Appl. No.: 11/506,130

(22) Filed: Aug. 17, 2006

(30) Foreign Application Priority Data
Dec. 21, 2005 (JP) 2005-367388

(51) Int. Cl. G01R 31/00

(52) U.S. Cl. 324/770

(57) ABSTRACT

A test method for a liquid crystal display panel in which the pixels providing liquid crystal elements having sealed in liquid crystal material are arranged in a matrix between opposing electrodes is comprised of a charging process for supplying charge to the above-mentioned liquid crystal element of a pixel under test, a measurement process for discharging the charge from the above-mentioned charged liquid crystal element and measuring the amount of charge discharged, and a decision process for determining whether defects are present in the liquid crystal element of the above-mentioned pixel under test from the above-mentioned measurement results.

### FIELD OF THE INVENTION

The present invention relates to a manufacturing method, test method, and test apparatus for a display panel, particularly to a manufacturing method, test method, and test apparatus for a liquid crystal display panel that seals in liquid crystal material.

### DISCUSSION OF THE BACKGROUND ART

A display apparatus using liquid crystal material is primarily constructed from a backlight as the light source, polarization filters for only transmitting light having specific polarizations, a display panel for controlling the light polarization state of each pixel, and color filters for producing three primary colors. Usually, the display panel is constructed with liquid crystal elements in an active matrix array that forms elements such as transistors and capacitors at each pixel on a substrate such as a glass plate.

FIG. 2 illustrates the structure of a liquid crystal element 233 of a typical liquid crystal display panel. Liquid crystal element 233 is comprised of a liquid crystal material 302; orientation films 301, 303 positioned to sandwich liquid crystal material 302 on both sides; and two electrodes 300, 304 positioned opposite each other to further sandwich the orientation films 301, 303 on the outside. One electrode 304 of the opposing electrodes is provided on a thin-film transistor (TFT) substrate.

Liquid crystal element 233 functions by rotating the incident polarized light by 90° when a voltage is not applied between electrodes 300, 304 and transmits the incident light unmodified when a voltage is applied between electrodes 300, 304. The light shield/transmit states are controlled by inputting the light that has passed through liquid crystal element 233 to the polarization filter. Consequently, when the voltage is not applied, the molecule groups of liquid crystal material 302 are not oriented in a uniform direction, and the shield/transmit states of the light cannot be skillfully controlled. Therefore, orientation films 301, 303 are provided between electrodes 300, 304 and liquid crystal material 302, and the liquid crystal molecule groups are oriented in a uniform direction.

All of the pixels on the liquid crystal display panel should have uniform characteristics. However, current manufacturing techniques have difficulty forming panels having stable characteristics over a wide area. For example, defects that develop due to various causes such as foreign materials exist inside the liquid crystal material; the gap between the opposing electrodes 300, 304 is nonuniform; defects arise in the stage of forming orientation films 301, 303; or the liquid crystal material 302 itself is nonuniform. Therefore, whether the panel has specific characteristics must be tested in the final manufacturing stage of a liquid crystal display panel.

In this type of test, the primary methods are optical tests as disclosed in Unexamined Japanese Patent Publication No. 2005-55196. In other words, these methods test each pixel in a state where light irradiates the finished liquid crystal panel, analyze the data acquired by image capture elements or light receiving elements from the side opposite the light source, and detect the presence or absence of defects in the liquid crystal display panel.

However, in optical tests, the positioning of the test apparatus and the liquid crystal display panel before conducting the test must be exact. Furthermore, to test a large area, a portion of the optical system such as the image capture elements and lenses must be physically driven during the test. Therefore, problems encountered include a long testing time and degradation in the measurement accuracy. Consequently, a test method capable of efficient and accurate data collection is sought.

### SUMMARY OF THE INVENTION

A test method for a liquid crystal display panel in which the pixels provided with liquid crystal elements that seal in liquid crystal material between opposing electrodes are arranged in a matrix shape and is comprised of a charging process for supplying a charge to charge the above-mentioned liquid crystal element of the pixel under test, a measurement means for measuring the amount of charge discharged from the above-mentioned charged liquid crystal element, and a decision process for deciding whether defects are present in the liquid crystal element of the above-mentioned pixel under test from the above-mentioned measurement results.

Because the liquid crystal material sealed between the opposing electrodes is a dielectric, when looked at electrically, the entire liquid crystal element has the same structure as a capacitor. Therefore, by detecting the defects produced between the opposing electrodes as abnormalities in the dielectric capacitance (abnormalities in the amount of stored charge), defects may be determined electrically. A test based on electrical methods does not have to exactly position the test apparatus and the panel as with an optical test apparatus because the test apparatus can be run simply by connecting the terminals of the liquid crystal display panel. In addition, a portion of the test apparatus does not have to be driven mechanically during the test. Furthermore, the dynamic characteristics as well as the static characteristics can be measured by changing the method for providing the stored charge. Various data required to identify the sources of defects can be collected.

A method for efficiently and accurately testing a liquid crystal display panel is provided by the present invention.

### BRIEF DESCRIPTION OF THE DRAWINGS

FIG. 1 is a schematic diagram of the test apparatus related to the present invention;

FIG. 2 is a schematic diagram of the liquid crystal display panel, which is the device under test; and

FIG. 3 is a flow chart of the operation of the test apparatus.

### DETAILED DESCRIPTION OF THE PREFERRED EMBODIMENT

Typical embodiments of the present invention are explained with reference to the drawings below.

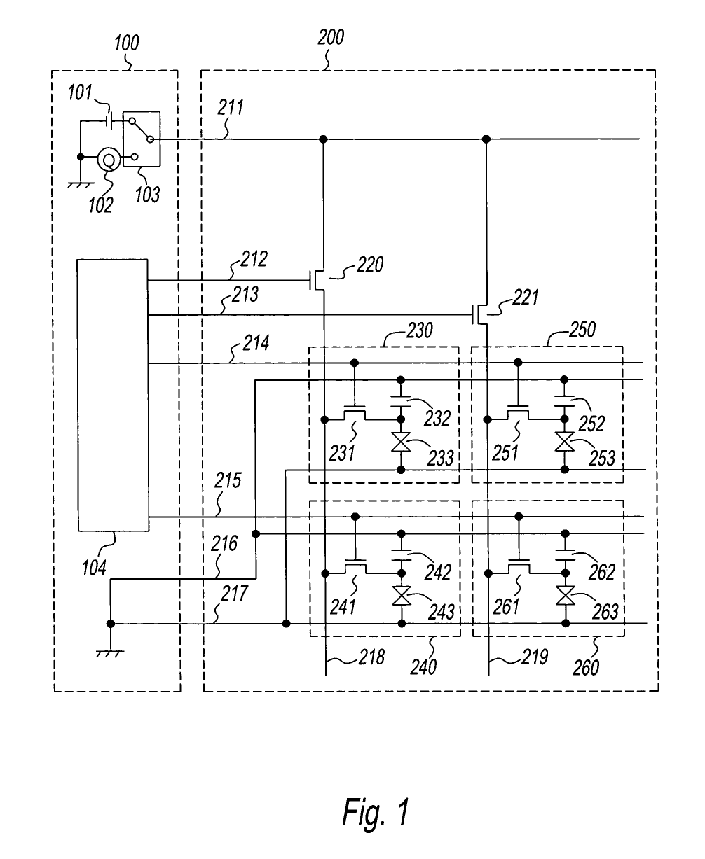

FIG. 1 is a schematic diagram showing a test apparatus 100 related to the present invention connected to a liquid crystal display panel 200, which is the device under test.

Liquid crystal display panel 200 comprises control wires 212, 213, 214, 215 for selecting pixels; signal wires 218, 219 that intersect each control wire and transmit analog control signals that control the states of the pixels; a transistor 220 for controlling the connection state between a signal input wire 211 from the outside and signal wire 218 on the basis of the input of control wire 212; a transistor 221 for controlling the connection state between signal input wire 211 from the outside and signal wire 219 on the basis of the input of control wire 213; pixels (230, 240, etc.) arranged at the intersections of the control wires and signal wires; a shared capacitance wire 216 for the reference potential of pixel capacitors (232, 242, etc.); and a shared liquid crystal wire 217 for the reference potential of liquid crystal elements (233, 243, etc.).

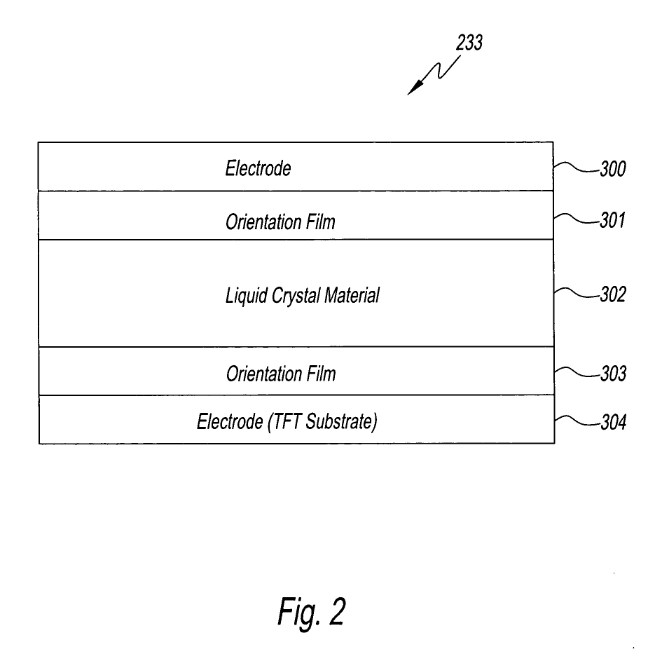

Pixel 230 comprises a transistor 231 which is a switching element where the gate terminal thereof is connected to control wire 214, and the drain terminal thereof is connected to signal wire 218; and a capacitor 232 and a liquid crystal element 233 connected serially to the source terminal of transistor 231. The other terminal of capacitor 232 is connected to shared capacitance wire 216. In liquid crystal element 233, the electrode on the side of the TFT active matrix substrate (electrode 304 in FIG. 2) connects to the source terminal of transistor 231, and the other electrode 300 connects to the shared liquid crystal wire 217.

The structures of the other pixels (240, 250, etc.) in liquid crystal display panel 200 have the same structure as pixel 230. The structure of the part sealing in the liquid crystal material of each pixel is the same structure as in FIG. 2 explained earlier.

Switching element 231 can be appropriately changed to functional elements other than a transistor as long as the element has the function that enables controlling the connection state between signal wire 218 and liquid crystal element 233. If both transistors 220, 221 function to control the connection states of signal input wire 211 and signal wires 218, 219, the transistors can be appropriately changed to, for example, a shift register.

Liquid crystal display panel 200 is connected to test apparatus 100. Test apparatus 100 comprises a control apparatus 104 for selecting the pixel under test and controlling the operation of the test apparatus; a power supply 101 for supplying charge to the pixel under test; a charge measurement apparatus 102 for measuring the amount of charge discharged from the pixel under test and deciding whether defects are present in the liquid crystal element; and a switching element 103 for selectively connecting power supply 101 and charge measurement apparatus 102 to signal input wire 211. Control wires 212, 213, 214, 215 are connected to control apparatus 104. Shared capacitance wire 216 and shared liquid crystal wire 217 are both connected to ground.

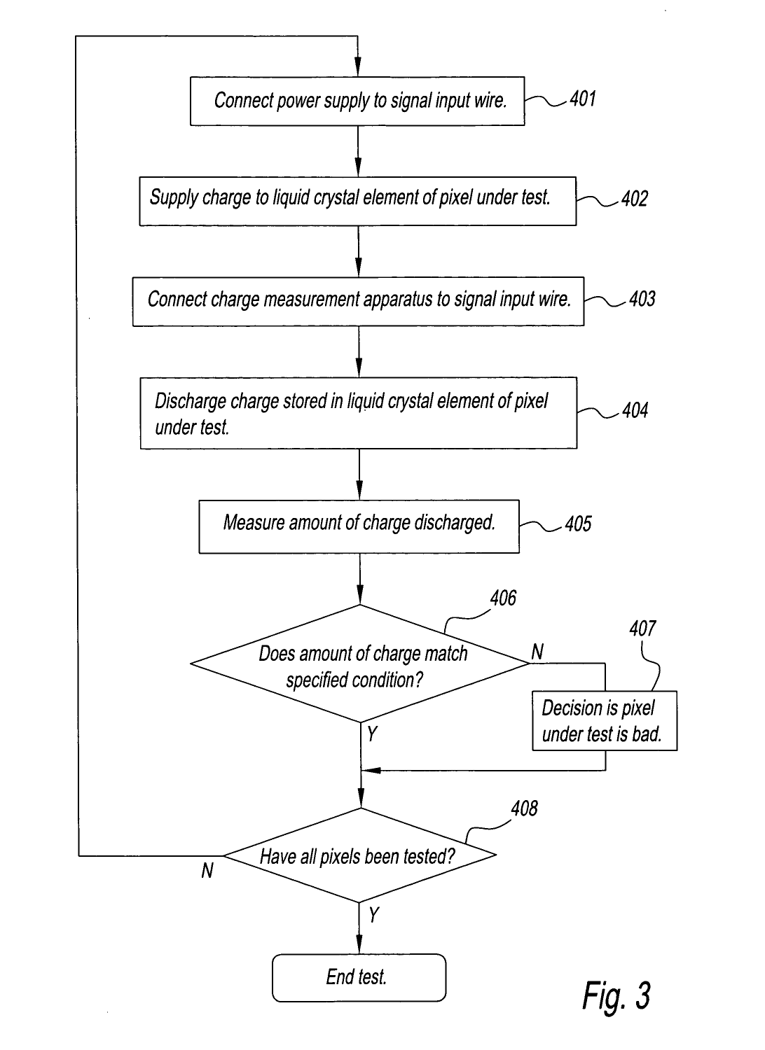

Next, the operation of test apparatus 100 is explained while referring to the flow chart in FIG. 3.

First, signal input wire 211 and power supply 101 are connected by switching element 103 (Step 401). The output of power supply 101 is set to the test voltage of 4 V. In this state, the on voltage is applied to control wire 212 and control wire 214. Then the pixel 230 placed at the intersection (row 1, column 1) of signal wire 218 connected to transistor 220 controlled by control wire 212 and control wire 214 is selected as the pixel under test.

The “on voltage” in the present application is the voltage where the switching element enters the conducting state (on state), that is, a voltage above the threshold voltage. In test apparatus 100, the on voltage of 8 V is given to control wire 214 in order to set transistor 231 in the on state.

On the other hand, the voltage where the switching element enters the off state is called the “off voltage.” When pixel 230 is tested, the off voltage of −5 V is given to control wire 215 because all of the pixels connected to control wire 215 must be set in the off state. The voltages and polarities of the on voltage and off voltage are appropriately set to match the specifications of the transistors and differ with the channel and type of transistor.

The operation of test apparatus 100 is explained again. By applying the on voltage to control wire 212, transistor 220 enters the on state, and signal input wire 211 and signal wire 218 enter the conducting state. By applying the on voltage to control wire 214, transistor 231 of pixel under test 230 enters the on state. Therefore, the charge supplied from power supply 101 passes through signal input wire 211, signal wire 218, and transistor 231, and is supplied to liquid crystal element 233 of pixel under test 230 (Step 402) (charging process).

Therefore, when the above charging process is executed, a transistor 251 of pixel 250 connected to control wire 214 enters the on state, but charge is not supplied to a liquid crystal element 253 because charge is not supplied to signal wire 219. In addition, charge is supplied to the drain terminal of a transistor 241 of pixel 240 connected to signal wire 218. However, charge is not supplied to a liquid crystal element 243 because transistor 241 itself is in the off state. In other words, charge is supplied only to liquid crystal element 233 of pixel under test 230 at row 1, column 1.

When the charging of liquid crystal element 233 ends, the off voltage is applied to control wire 214, and transistor 231 enters the off state, and signal wire 218 and liquid crystal element 233 are disconnected. After a specific time has elapsed, charge measurement apparatus 102 connects to signal input wire 211, and transistor 231 enters the on state again (Step 403). The charge that charged electrode 304 of pixel under test 230 is discharged through transistor 231 to signal wire 218 (Step 404). The discharged charge passes through signal input wire 211, flows into charge measurement apparatus 102, and the amount of charge is measured (Step 405, measurement process).

Charge measurement apparatus 102 determines whether the measurement result conforms to the specified conditions (Step 406). For example, when the amount of charge is extremely small, it is decided that a leak exists between opposing electrodes 300, 304. Even if there is no leakage current when the amount of charge is not in the specified range, it is decided that a foreign material exists inside the liquid crystal material 302, or the distance between opposing electrodes 300, 304 is unsuitable. When a foreign material exists or the distance between opposing electrodes 300, 304 is not appropriate, the amount of measured charge differs because the dielectric capacity differs compared to the normal case.

When faults such as a leakage current or foreign materials are confirmed, defects occur in liquid crystal element 233, and it is decided that pixel under test 230 is a bad pixel. The position of the pixel under test, the amount of measured charge, and the hypothesized cause of the defect are recorded (Step 407, decision process). This completes the test of pixel 230 at row 1, column 1.

The same test process sequentially tests pixel 240 at row 1, column 2; and the pixel at row 1, column 3 (not shown), . . . . When all of the pixels in row 1 have been tested, pixel 250 at row 2, column 1; pixel 260 at row 2, column 2, . . . are sequentially tested, and all of the pixels in the second row are tested. Similarly each pixel in the third row and each pixel in the fourth row, . . . are sequentially tested. When all of the pixels have been tested, the test process of display panel 200 ends (Step 408).

The above testing sequence of the pixels is one example, but the testing is not limited to this. For example, after testing pixel 230 at row 1, column 1, the test may scan in the row direction and test pixel 250 at row 2, column 1; the pixel at row 3, column 1, . . . . In addition, when the stability and the reliability are high in the manufacturing process of the liquid crystal display panel, all of the pixels do not have to be tested, and specific pixels may be sampled and tested.

In the above embodiment, only the static characteristics of pixel under test 230 were measured. However, the dynamic characteristics may also be measured by measuring the amount of charge discharged a plurality of times over a period of time to measure the temporal variations, by measuring the differences in the amount of charge discharged from liquid crystal element 233 when the test voltage (4 V) is applied after the reversed charge is given to liquid crystal element 233 (applied voltage of power supply 101 set to −4 V and charged), or when the test voltage is applied from the uncharged state as described above. Furthermore, other defect modes, for example, defects of the orientation films or poor liquid crystal material, can be ascertained.

Above, the technical concepts related to the present invention were explained in detail while referring to specific embodiments. However, a person skilled in the art of the present invention can add various changes and improvements without diverging from the intent and scope of the claims.

What is claimed is:

1. A test method for a liquid crystal display panel in which the pixels providing liquid crystal elements having sealed in liquid crystal material are provided between opposing electrodes and arranged in a matrix, said method comprises:
supplying a charge to said liquid crystal element of a pixel under test;
discharging the charge from said charged liquid crystal element and measuring the amount of charge discharged; and
determining whether defects are present in the liquid crystal element of said pixel under test from said measurement results.

2. The test method for a liquid crystal display panel of claim 1, wherein said determining step comprises a process for determining either the static characteristics or the dynamic characteristics or both of said liquid crystal element.

3. A manufacturing method for a liquid crystal display panel in which the pixels providing liquid crystal elements having sealed in liquid crystal material are provided between opposing electrodes and arranged in a matrix, said method comprises testing for the presence or absence of defects in said liquid crystal elements, wherein said testing comprises:
supplying a charge to said liquid crystal element of the pixel under test;
discharging the charge from said charged liquid crystal element and measuring the amount of charge discharged; and
determining whether defects are present in the liquid crystal element of said pixel under test from said measurement results.

4. A test method for a liquid crystal display panel that has a plurality of control wires, a plurality of signal wires that intersect said plurality of control wires, and pixels arranged at the intersecting positions of said control wires and said signal wires, and said pixel has a liquid crystal element and a switching element for controlling the connection states of the liquid crystal element and said data wire on the basis of signals in said control wire, wherein the test method for a liquid crystal display panel comprises:
setting the switching element of the pixel under test in the conducting state, supplying charge to the signal wire connected to said switching element, and storing charge in said liquid crystal element;
discharging the charge stored in the liquid crystal element of said pixel under test to said signal wire and measuring the amount of charge discharged; and
determining whether said measured amount of charge satisfies the specified conditions and whether defects are present in the liquid crystal element of said pixel under test.

5. A test apparatus for a liquid crystal display panel that has a plurality of control wires, a plurality of signal wires that intersect said plurality of control wires, and pixels arranged at the intersecting positions of said control wires and said signal wires, and said pixel has a liquid crystal element and a switching element for controlling the connection state of said signal wire and said liquid crystal element on the basis of signals in said control wire, wherein said test apparatus comprises:
a power supply;
a charge measurement apparatus; and
a control apparatus for determining whether defects are present in the liquid crystal element of said pixel under test in said charge measurement apparatus by connecting said power supply to said signal wire which is connected to the pixel under test, giving charge to the liquid crystal element of said pixel under test, then discharging said stored charge, measuring the amount of charge discharged by said charge measurement apparatus, and determining whether said amount of charge satisfies the specified conditions.
